(19) United States
(12) Patent Application Publication
(10) Pub. No.: US 2025/0048605 A1
(43) Pub. Date: Feb. 6, 2025

(54) SEMICONDUCTOR DEVICE AND INSULATING MEMBER

(71) Applicant: HITACHI ASTEMO, LTD., Hitachinaka-shi, Ibaraki (JP)

(72) Inventors: Takahiro SHIMURA, Hitachinaka-shi, Ibaraki (JP); Shoichi SAKAI, Hitachinaka-shi, Ibaraki (JP); Junpei KUSUKAWA, Tokyo (JP)

(73) Assignee: HITACHI ASTEMO, LTD., Hitachinaka-shi, Ibaraki (JP)

(21) Appl. No.: 18/717,691

(22) PCT Filed: Dec. 15, 2021
(86) PCT No.: PCT/JP2021/046351

§ 371 Date: Jun. 7, 2024

(51) Int. Cl. H05K 7/20; H01L 23/473; H02M 3/00

(52) U.S. Cl. CPC H05K 7/20927; H01L 23/473; H02M 3/003; H05K 7/209

(57) ABSTRACT

The semiconductor device includes a first conductor member to which a switching element is connected; a second conductor member to which a switching element is connected; a heat dissipation member arranged to face the first and second conductor members arranged in parallel; and an insulating member having an electrical insulation layer that contains a first intermediate conductor facing the first conductor member, a second intermediate conductor facing the second conductor member, and the first and second intermediate conductors, the insulating member being disposed between the first and second conductor members arranged in parallel and the heat dissipation member, wherein the electrical insulation layer has a first insulation layer where the first intermediate conductor is disposed, a second insulation layer where the second intermediate conductor is disposed, and a third insulation layer interposed between the first insulation layer and the second insulation layer.

### TECHNICAL FIELD

The present invention relates to a semiconductor device and an insulating member used in the semiconductor device.

### BACKGROUND ART

In a power module, insulation layers such as insulation sheets are provided between lead frames whereon power semiconductor elements are arranged, and the heat dissipation wall of a module case. The heat dissipation wall is formed of a conductive member and is connected to earth ground (GND) for voltage stabilization. For the power module disclosed in PTL 1, a structure is adopted in which an intermediate conductor is disposed in each insulation layer opposed by the lead frames of the upper and lower arms to divide a voltage applied to the insulation layer. When the power module is assembled, two intermediate conductors are sandwiched between two insulation sheets, and the insulation sheets sandwiching the intermediate conductors are arranged between the lead frames of the upper and lower arms and the heat dissipation wall.

### CITATION LIST

### Patent Literature

PTL 1: Japanese Patent No. 6200871

### SUMMARY OF INVENTION

### Technical Problem

However, in order to secure a voltage division function, it is preferable to arrange the intermediate conductors to oppose the whole of the lead frames, and thus the two intermediate conductors opposing the lead frames of the upper and lower arms are juxtaposed at a slight interval. When the intermediate conductors are arranged between the insulation sheets, it is necessary to perform alignment so that the intermediate conductors do not contact each other, which causes a decrease in productivity in the assembly work.

### Solution to Problem

A semiconductor device according to an aspect of the present invention includes: a first conductor member to which a switching element on an upper arm side of an inverter circuit is connected; a second conductor member to which a switching element on a lower arm side of the inverter circuit is connected; a heat dissipation member arranged to face the first and second conductor members arranged in parallel; and an insulating member having an electrical insulation layer that contains a first intermediate conductor facing the first conductor member, a second intermediate conductor facing the second conductor member, and the first and second intermediate conductors, the insulating member being disposed between the first and second conductor members arranged in parallel and the heat dissipation member, wherein the electrical insulation layer has a first insulation layer in which the first intermediate conductor is disposed, a second insulation layer in which the second intermediate conductor is disposed, and a third insulation layer interposed between the first insulation layer and the second insulation layer.

### Advantageous Effects of Invention

The present invention enables contact between the intermediate conductors to be prevented and productivity to be improved.

### BRIEF DESCRIPTION OF DRAWINGS

FIG. 1 is a circuit diagram illustrating a circuit configuration of a semiconductor device according to the present embodiment.

FIG. 2 is an exploded perspective view of the power module.

FIG. 3 is an exploded perspective view of a circuit molded body.

FIG. 4 is a cross-sectional view showing a cross-section (xy cross-section) of a power module.

FIG. 5 is a diagram illustrating an arrangement of intermediate conductors in a first arrangement state.

FIG. 6 is a diagram illustrating an arrangement of intermediate conductors in a second arrangement state.

FIG. 7 is a plan view of a heat dissipation sheet.

FIG. 8 is a cross-sectional view taken along line A-A of FIG. 7.

FIG. 9 is a diagram illustrating an example of a procedure for manufacturing the heat dissipation sheet.

FIG. 10 is a diagram illustrating a heat dissipation sheet provided on one surface of the circuit molded body.

FIG. 11 is a diagram for a case where d5=0 in FIG. 10.

FIG. 12 is a diagram illustrating a state in which the heat dissipation sheet in the configuration of FIG. 11 is shifted rightward in the drawing.

### DESCRIPTION OF EMBODIMENTS

Hereinafter, an embodiment of a semiconductor device according to the present invention will be described with reference to the drawings. The following description and drawings are examples to illustrate the present invention, and are omitted and simplified as appropriate for the sake of clarity of description. In the following description, the same or similar elements and processes are denoted by the same reference signs, and redundant descriptions may be omitted. Note that the content described below is merely an example of an embodiment of the present invention, and the present invention is not limited to or by the following embodiment, and can be implemented in other various forms.

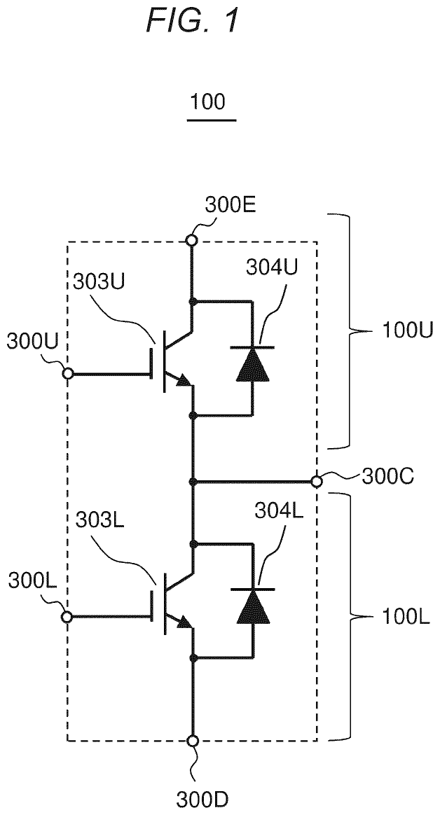

FIG. 1 is a circuit diagram illustrating a circuit configuration of a semiconductor device according to a present embodiment. The semiconductor device according to the present embodiment is provided in, for example, an inverter circuit of a power conversion device mounted on an electric vehicle, a hybrid vehicle, or the like, and is also referred to as a power module. Hereinafter, the term power module is used instead of semiconductor device. The power conversion device performs power conversion between a DC power supply and a motor generator (for example, a three-phase AC-type rotary electric machine) for vehicle travel. The power conversion device includes a smoothing capacitor and an inverter circuit constituting a power converter. The inverter circuit converts the inputted DC power into a three-phase alternating current of a predetermined frequency, and outputs the three-phase alternating current to the motor. Conversely, the alternating current generated by the generator is converted into a direct current and outputted. The inverter circuit includes, for example, a three-phase power module. FIG. 1 illustrates a circuit diagram of a single-phase power module 100.

The circuit of the power module 100 includes an upper arm 100U and a lower arm 100L which are connected in series. The upper arm 100U includes a power semiconductor element 303U and a diode 304U. The lower arm 100L includes a power semiconductor element 303L and a diode 304L. The power semiconductor elements 303U and 303L include, for example, an insulated-gate bipolar transistor (IGBT), a FET, or the like. The power semiconductor element 303U of the upper arm 100U is on/off controlled by a control signal inputted to an upper arm control terminal 300U. Similarly, the power semiconductor element 303L of the lower arm 100L is on/off controlled by a control signal inputted to a lower arm control terminal 300L.

An externally connected P terminal 300E of the upper arm 100U is connected to the high potential power line of a DC power supply, and an externally connected N terminal 300D of the lower arm 100L is connected to a low potential power line of the DC power supply. An externally connected AC terminal 300C is provided at a connection point between the upper arm 100U and the lower arm 100L, and outputs an alternating current from the externally connected AC terminal 300C to an external device (for example, a motor). A capacitor or the like is connected to the DC power supply line in parallel with the upper and lower arms 100U and 100L.

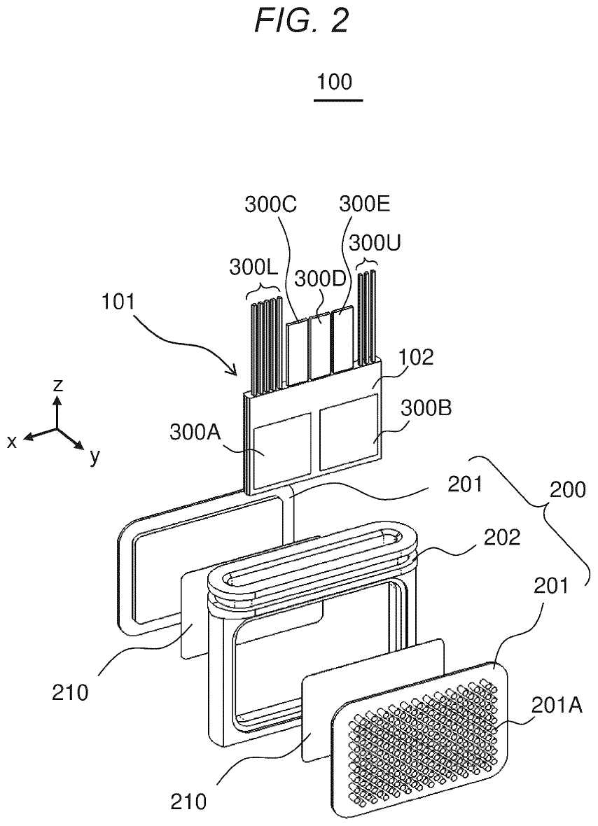

FIG. 2 is an exploded perspective view of the power module 100. The power module 100 includes a circuit molded body 101, a heat dissipation sheet 210, and a case 200. The power semiconductor elements 303U and 303L and the diodes 304U and 304L illustrated in FIG. 1 are provided to the circuit molded body 101 and are sealed by a sealing member 102 formed of an electrically insulating material. The case 200 includes a frame body 202 and two heat dissipation members 201. A pin fin 201A is formed on the outer surfaces of the heat dissipation members 201. The heat dissipation members 201 are joined with watertightness to the frame body 202. For example, the heat dissipation members 201 are joined to the frame body 202 through friction-stir welding (FSW welding) or the like.

The circuit molded body 101 is housed in the case 200, and the heat dissipation sheet 210 is disposed between the circuit molded body 101 and the heat dissipation members 201. The heat dissipation sheet 210 is formed of an electrically insulating material, and an intermediate conductor is provided inside the heat dissipation sheet, as will be described below. The heat dissipation sheet 210 adheres gaplessly to the circuit molded body 101 and the heat dissipation members 201. The heat dissipation sheet 210 is formed of, for example, a resin having high level of electrical insulation, adhesiveness, and thermal conductivity, and possesses a function for electrically insulating the circuit molded body 101 and the heat dissipation members 201 and a function for releasing heat from the circuit molded body 101 to the heat dissipation members 201. The gap in the case 200 is filled with an electrically insulating resin and sealed.

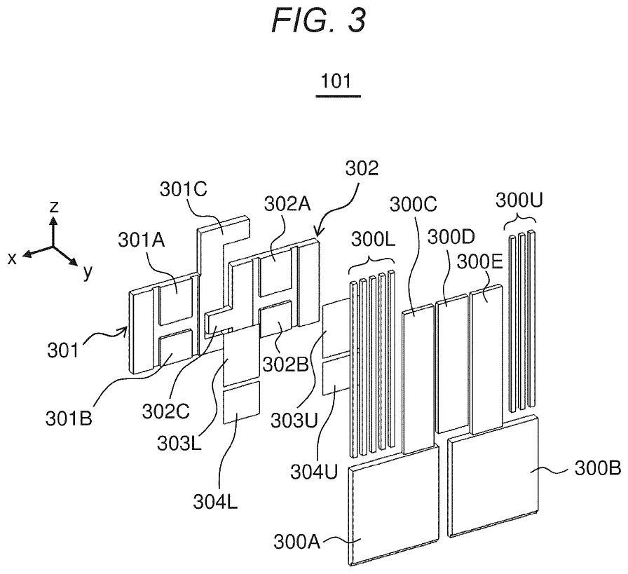

FIG. 3 is an exploded perspective view of the circuit molded body 101. Note that illustration of the sealing member 102 is omitted. Connection terminals of the power semiconductor elements 303U and 303L and the diodes 304U and 304L are formed on both the front and back surfaces of a plate-like element. The power semiconductor element 303U and the diode 304U of the upper arm 100U are electrically connected to an AC lead frame 302 and an upper arm base 300B, which are conductor members, so as to be sandwiched therebetween. Similarly, the power semiconductor element 303L and the diode 304L of the lower arm 100L are electrically connected to the N lead frame 301 and the lower arm base 300A, which are conductor members, so as to be sandwiched therebetween. Soldering or the like is used for the connection.

In the AC lead frame 302, a convex portion 302A to which the power semiconductor element 303U is connected, a convex portion 302B to which the diode 304U is connected, and an AC connecting portion 302C are formed. In the N lead frame 301, a convex portion 301A to which the power semiconductor element 303L is connected, a convex portion 301B to which the diode 304L is connected, and an N connecting portion 301C are formed. The convex portion 301A, the convex portion 301B, the convex portion 302A, and the convex portion 302B have high planar accuracy.

The upper arm base 300B includes an externally connected P terminal 300E. The lower arm base 300A has an externally connected AC terminal 300C. The AC connecting portion 302C of the AC lead frame 302 is electrically connected to the lower arm base 300A through soldering. The N connecting portion 301C of the N lead frame 301 is electrically connected to the externally connected N terminal 300D through soldering. The upper arm control terminal 300U and the lower arm control terminal 300L are electrically connected to control electrodes of the corresponding power semiconductor elements 303U and 303L, respectively, by means of wire bonding or the like.

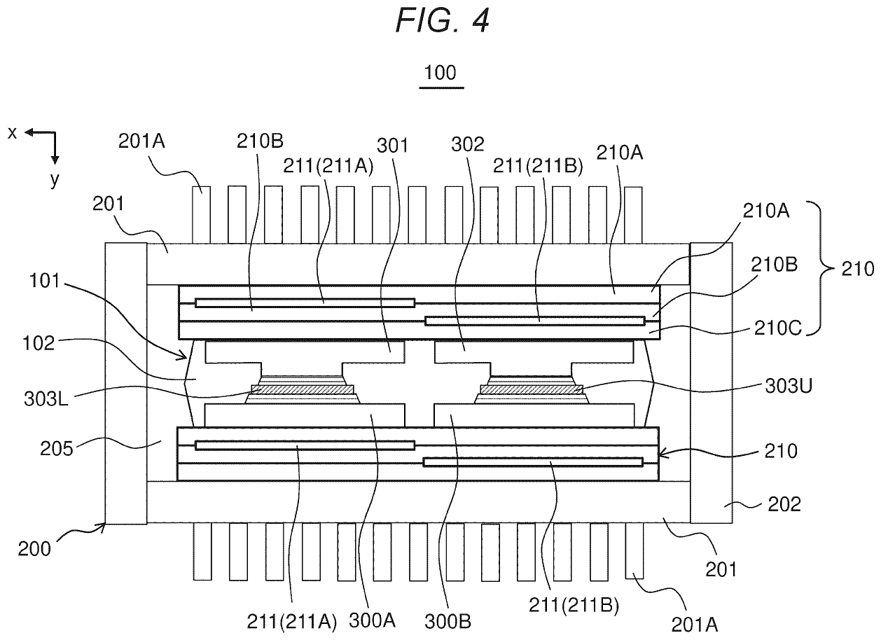

FIG. 4 is a cross-sectional view showing a cross-section (xy cross-section) of the power module 100. In the circuit molded body 101, the power semiconductor elements 303U and 303L, the diodes 304U and 304L, the AC lead frame 302, the N lead frame 301, the upper arm base 300B, and the lower arm base 300A are sealed by a sealing member 102. Surfaces of the N lead frame 301, the AC lead frame 302, the lower arm base 300A, and the upper arm base 300B, which are conductor members facing the heat dissipation members 201 are exposed from m the sealing member 102. The heat dissipation sheet 210 is disposed between the circuit molded body 101 and the heat dissipation members 201. Both surfaces of the heat dissipation sheet 210 are closely bonded to the circuit molded body 101 and the heat dissipation members 201 using an adhesive, grease, or the like. The gap space between the circuit molded body 101 and the heat dissipation sheet 210, and the case 200 is filled gaplessly with a sealing resin 205.

Although not illustrated, the case 200 of the power module 100 in FIG. 4 is disposed in a cooling water passage of an inverter main body. Cooling water flows through the area of the pin fins 201A of the heat dissipation members 201, and the heat generated by the power module 100 is dissipated from the heat dissipation members 201 to the cooling water.

An alternating current flows through the lower arm base 300A having the externally connected AC terminal 300C and the AC lead frame 302 connected to the lower arm base 300A. Meanwhile, a direct current flows through the upper arm base 300B having the externally connected P terminal 300E and the N lead frame 301 connected to the externally connected N terminal 300D.

When an air layer due to peeling occurs between the heat dissipation sheet 210 and each of the N lead frame 301, the lower arm base 300A, the AC lead frame 302, and the upper arm base 300B, which are conductor members, or when an air layer such as a void occurs inside the heat dissipation sheet 210, corona discharge is likely to occur in cases where a high voltage is applied. When corona discharge occurs, the heat dissipation sheet 210 formed of a resin material deteriorates, and insulation durability deteriorates significantly. Therefore, intermediate conductors 211 (211A, 211B) for dividing the voltage between the conductor members and the heat dissipation members 201 is provided in the heat dissipation sheet 210.

By the way, corona discharge is more likely to occur on the side of the lower arm base 300A and the AC lead frame 302 through which alternating current flows than on the side of the upper arm base 300B and the N lead frame 301 through which direct current flows. Therefore, the positions of the intermediate conductors 211 in the heat dissipation sheet 210 are biased toward the lower arm base 300A and the AC lead frame 302 such that the divided voltage between the lower arm base 300A and the AC lead frame 302 and the intermediate conductors 211 is smaller than the divided voltage between the intermediate conductors 211 and the heat dissipation members 201.

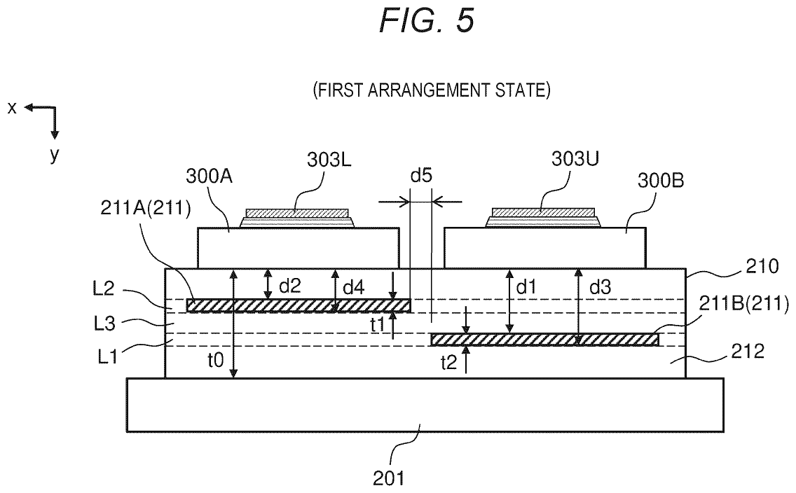

FIG. 5 is a diagram illustrating the arrangement of the intermediate conductors 211 (211A, 211B) with respect to the lower arm base 300A and the upper arm base 300B. In order to perform effective voltage division, the intermediate conductors 211 need to face at least the whole conductor member. Furthermore, when the positional displacement of the heat dissipation sheet 210 at the time of assembly is taken into account, it is preferable to have an area larger than the region opposing the conductor member. In the conventional power module disclosed in PTL 1, because the two intermediate conductors 211A and 211B are arranged in parallel on the same plane, there is a possibility of the intermediate conductors coming into contact with each other due to misalignment of the intermediate conductors. Therefore, in order to prevent the intermediate conductors from coming into contact with each other, that is, in order to prevent the interval d5 from satisfying d5<0, it is necessary to strictly control the accuracy of the size and position of the intermediate conductors 211.

Therefore, in the present embodiment, by setting the arrangement of the intermediate conductors 211A and 211B as follows, contact between the intermediate conductors 211A and 211B is prevented. The main points of the arrangement setting are as follows. As illustrated in FIG. 5, the heat dissipation sheet 210 includes intermediate conductors 211A and 211B and an electrical insulation layer 212 including the intermediate conductors 211A and 211B. The intermediate conductor 211A is disposed in a region facing the lower arm base 300A, and the intermediate conductor 211B is disposed in a region facing the upper arm base 300B. The electrical insulation layer 212 includes a first insulation layer L1 where the intermediate conductor 211B is disposed, a second insulation layer L2 where the intermediate conductor 211A is disposed, and a third insulation layer L3 interposed between the first insulation layer L1 and the second insulation layer L2.

In the heat dissipation sheet 210 described above, the third insulation layer L3 is: interposed between the intermediate conductor 211A and the intermediate conductor 211B. Therefore, when the intermediate conductors 211A and 211B are projected from the heat dissipation members 201 in the direction of the conductor members (the lower arm base 300A and the upper arm base 300B), there is no possibility of the intermediate conductors 211A and 211B coming into contact with each other even when the intermediate conductors 211A and 211B appear to be positionally displaced so as to partially overlap each other. Furthermore, the sizes (areas) of the intermediate conductors 211A and 211B can be made as large as possible while preventing contact between the intermediate conductors 211A and 211B, and thus the divided voltage function by the intermediate conductors 211A and 211B can be afforded adequately.

In the main points of the arrangement setting described above, the arrangement configuration of the intermediate conductors 211A and 211B has been qualitatively described. Hereinafter, the arrangement setting of the intermediate conductors 211A and 211B will be quantitatively described using the distance between the intermediate conductors 211A and 211B and the conductor member facing the intermediate conductors. As the intermediate conductors 211A and 211B, for example, very thin conductor plates such as copper foils may be used, but here, distance setting will be described assuming that the thicknesses of the intermediate conductors 211A and 211B are t2 and t1 as illustrated in FIG. 5.

In FIG. 5, to is the thickness of the heat dissipation sheet 210. d1 and d3 are distances from the upper arm base 300B (conductor member) to the conductor member side-facing surface and the heat dissipation member side-facing surface of the intermediate conductor 211B. d2 and d4 are distances from the lower arm base 300A (conductor member) to the conductor member side-facing surface and the heat dissipation member side-facing surface of the intermediate conductor 211A. d5 is an x-direction interval between the intermediate conductor 211A and the intermediate conductor 211B.

As illustrated in FIG. 5, in the case of d2<d1 where the intermediate conductor 211A is closer to the conductor member (lower arm base 300A), as denoted by d4<d1, the distance d4 from the lower arm base 300A to the heat dissipation member side-facing surface of the intermediate conductor 211A is set to be smaller than the distance d1 from the upper arm base 300B to the conductor member side-facing surface of the intermediate conductor 211B. This state is referred to as the first arrangement state.

Meanwhile, contrary to the case of FIG. 5, in the case of d1<d2 where the intermediate conductor 211B is closer to the conductor member (upper arm base 300B), as denoted by d2>d3, the distance d2 from the lower arm base 300A to the conductor member side-facing surface of the intermediate conductor 211A is set to be larger than the distance d3 from the upper arm base 300B to the heat dissipation member side-facing surface of the intermediate conductor 211B. This state is referred to as the second arrangement state. In this manner, by setting the first arrangement state or the second arrangement state, it is possible to prevent the intermediate conductors 211A and 211B in the heat dissipation sheet 210 from coming into contact due to positional displacement or the like.

When t1=t2, the arrangement condition in the case of FIG. 5 is expressed by the following formula (1) using d1, d2, and t1.

$$d 2 < d 1 - t 1 \qquad ( 1 )$$

Conversely, in a case where the intermediate conductor 211B is closer to the conductor member (upper arm base 300B), the arrangement condition under which contact can be prevented is expressed by the following formula (2) instead of formula (1).

$$d 1 < d 2 - t 1 \qquad ( 2 )$$

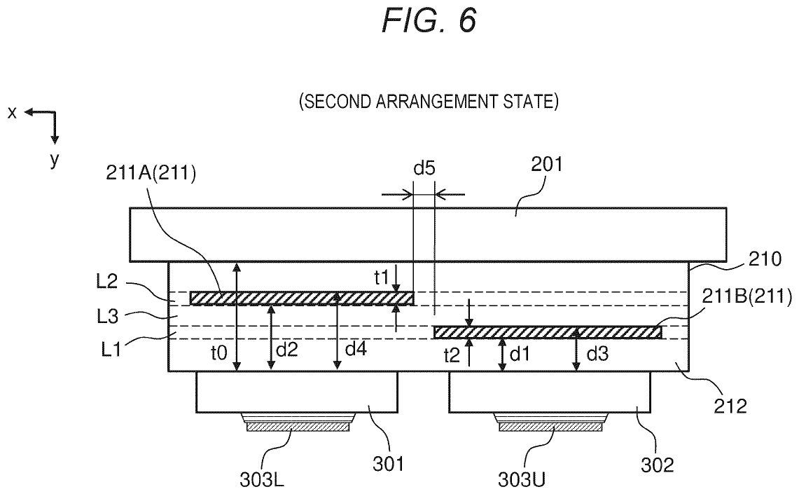

FIG. 6 is a diagram illustrating the arrangement of the intermediate conductors 211A and 211B on the side of the N lead frame 301 and the AC lead frame 302. The same applies to the intermediate conductors 211A and 211B on the N lead frame 301 and AC lead frame 302 sides, respectively, and it is possible to prevent contact between the intermediate conductors 211A and 211B in the heat dissipation sheet 210 by establishing the above-described first arrangement state or the second arrangement state. FIG. 6 illustrates a second arrangement state. That is, in the case of d1<d2 in which the intermediate conductor 211B is closer to the conductor member (AC lead frame 302), as denoted by d2>d3, the distance d2 from the N lead frame 301 to the conductor member side-facing surface of the intermediate conductor 211A is set to be larger than the distance d3 from the AC lead frame 302 to the heat dissipation member side-facing surface of the intermediate conductor 211B.

As described above, corona discharge is more likely to occur on the side of the lower arm base 300A and the AC lead frame 302 through which alternating current flows than on the side of the upper arm base 300B and the N lead frame 301 through which direct current flows. Therefore, as in the first arrangement state illustrated in FIG. 5, the intermediate conductor 211A on the lower arm base 300A side is preferably arranged closer to the conductor member (d2<d1). Meanwhile, in the case of the N lead frame 301 and the AC lead frame 302 illustrated in FIG. 6, because the alternating current flows through the AC lead frame 302, the second arrangement state illustrated in FIG. 6 in which d1<d2 is preferable.

Furthermore, in order to suppress the occurrence of the corona discharge as much as possible, the potential difference between the intermediate conductor 211A and the lower arm base 300A (conductor member) through which the alternating current flows is preferably made smaller than the potential difference between the heat dissipation members 201 and the intermediate conductor 211A. That is, the intermediate conductor 211A is disposed so as to be biased toward the lower arm base 300A through which an alternating current flows from the center of the heat dissipation sheet 210 so as to satisfy the following formula (3) in addition to the above-described arrangement conditions.

$$d 2 < ( t 0 - t 1 ) / 2 \qquad ( 3 )$$

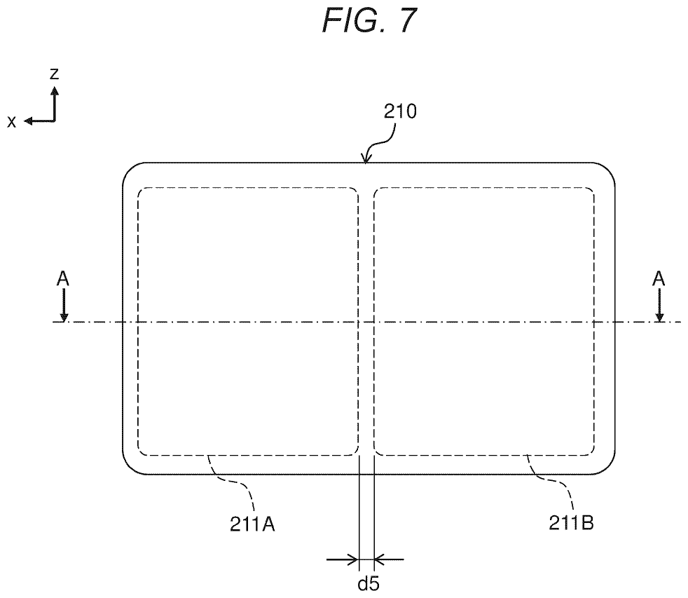

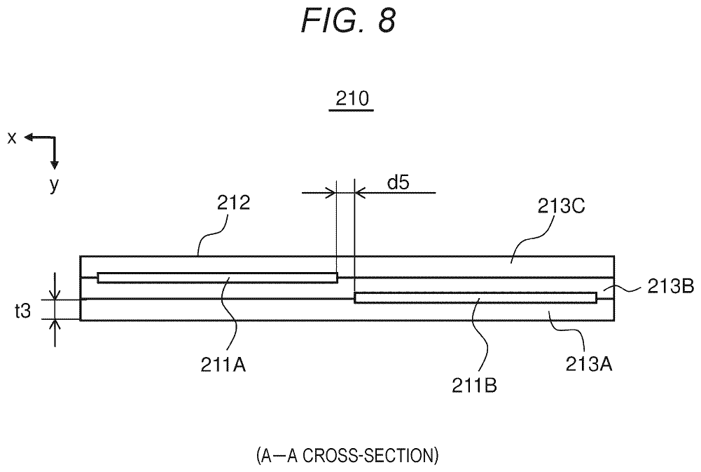

FIGS. 7 and 8 are diagrams illustrating an example of the heat dissipation sheet 210. In FIGS. 5 and 6, a configuration in which the electrical insulation layer 212 of the heat dissipation sheet 210 is molded using an insulating resin has been described as an example, but in FIGS. 7 and 8, a case where the electrical insulation layer 212 is formed of a plurality of insulation sheets will be described. FIG. 7 is a plan view of the heat dissipation sheet 210, and FIG. 8 is a cross-sectional view taken along line A-A in FIG. 7. As illustrated in FIG. 7, substantially rectangular intermediate conductors 211A and 211B are provided inside the heat dissipation sheet 210. As illustrated in the cross-sectional view taken along line A-A of FIG. 8, the electrical insulation layer 212 of the heat dissipation sheet 210 has a structure in which three insulation sheets 213A, 213B, and 213C are stacked in layers. The insulation sheets 213A, 213B, and 213C are formed of resin-based members of the same material, and have the same thickness t3 and the same shape. The intermediate conductor 211A is sandwiched between the insulation sheets 213B and 213C, and the intermediate conductor 211B is sandwiched between the sheets insulation 213A and 213B. The intermediate conductors 211A and 211B are formed of a conductive material such as a copper foil, for example.

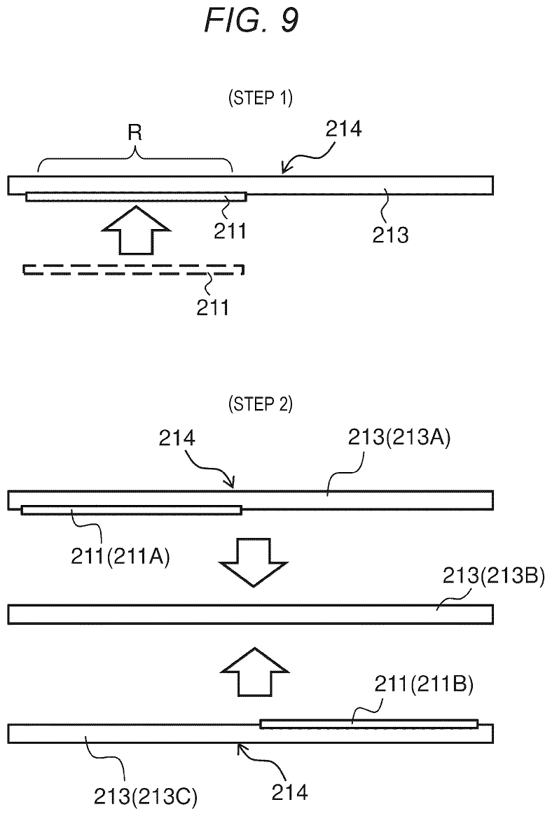

FIG. 9 is a diagram illustrating an example of a procedure for manufacturing the heat dissipation sheet 210. In step 1, the intermediate conductor 211 is bonded to form the intermediate conductor-attached sheet 214 so as to cover a region R which is opposed by the conductor member on one surface of the insulation sheet 213. In step 2, the intermediate conductor-attached sheet 214 on which the intermediate conductors 211 are arranged so as to oppose each other in the left and right direction is bonded to the front and back surfaces, respectively, of the insulation sheet 213 (213B). That is, the intermediate conductor-attached sheet 214 is bonded to the upper surface of the insulation sheet 213 (213B) in the drawing such that the intermediate conductor 211 (211A) faces the region on the left side of the insulation sheet 213 (213B) in the drawing. Meanwhile, the intermediate conductor-attached sheet 214 is bonded to the lower surface of the insulation sheet 213 (213B) in the drawing such that the intermediate conductor 211 (211B) faces the region on the right side of the insulation sheet 213 (213B) in the drawing. At the time of adhesion, the bonding is performed so that no gap is formed in the bonding region. In a case where the insulation sheet has adhesiveness, the insulation sheet may be integrated using adhesiveness without using an adhesive.

In addition, the intermediate conductors 211A and 211B may be fixed to the front and back surfaces of the insulation sheet 213B to form an intermediate conductor-attached sheet 214A. In this case, the heat dissipation sheet 210 is formed by stacking the insulation sheets 213A and 213B on the front and back surfaces of the intermediate conductor-attached sheet 214A to which the intermediate conductors 211A and 211B are fixed.

Here, for the three insulation sheets 213A, 213B, and 213C, insulation sheets having the same shape, the same thickness, and the same material are used. As described above, the stacked insulation sheets 213A, 213B, and 213C are crimped so that a gap is not formed in the bonding region. Therefore, even when the thickness is t3, for example, the upper and lower sheet regions of the intermediate conductors 211A and 211B are compressed, and the thickness is slightly thinner than t3, as illustrated in FIG. 8. In addition, conductive materials (for example, copper foil) having the same shape, the same thickness, and the same material are also used for the two intermediate conductors 211A and 211B.

As described above, in the heat dissipation sheet 210 illustrated in FIGS. 8 and 9, components can be made common, and thus productivity can be improved. Because the insulation sheet 213B disposed between the two intermediate conductors 211A and 211B has a function for preventing contact between the intermediate conductors 211A and 211B, the insulation sheet 213B may be made thinner than the other insulation sheets 213A and 213C when it is necessary to reduce thermal resistance.

In a case where the heat dissipation sheet 210 illustrated in FIG. 8 is disposed between the lower arm base 300A and the upper arm base 300B in FIG. 4 and the heat dissipation members 201, the lower surface in the drawing of the heat dissipation sheet 210 is disposed to face the heat dissipation members 201. Meanwhile, in a case where the heat dissipation sheet 210 is disposed between the N lead frame 301 and the AC lead frame 302 in FIG. 4 and the heat dissipation members 201, the upper surface of the heat dissipation sheet 210 in FIG. 8 may be disposed to face the heat dissipation members 201.

In the case of the heat dissipation sheet 210 illustrated in FIGS. 7 and 8, the intermediate conductors 211A and 211B are arranged between different layers of the three layers of insulation sheets 213A to 213C. Therefore, even in a case where the intermediate conductors 211A and 211B appear to have an overlapping region when projected in the y direction in FIG. 8, the intermediate conductors 211A and 211B do not come into contact with each other due to positional displacement or the like of the intermediate conductors 211A and 211B because the insulation sheet 213B between the intermediate conductors 211A and 211B is interposed therebetween. As a result, in the work of stacking the intermediate conductors 211A and 211B and the insulation sheets 213A to 213C, strict positioning accuracy is not required, and thus workability can be improved.

Furthermore, the distance between the intermediate conductors 211A and 211B and the conductive member is automatically determined depending on which insulation sheet layers the intermediate conductors 211A and 211B are arranged between. Therefore, at the time of manufacturing the heat dissipation sheet 210, the positioning accuracy of the intermediate conductors 211A and 211B in the y direction in the heat dissipation sheet 210 is unimportant. Thus, by adopting a structure in which the intermediate conductors 211A and 211B are arranged between different layers of the heat dissipation sheet 210 which has a three-layer structure formed of the three insulation sheets 213A to 213C, it is possible to easily form an arrangement structure in which the intermediate conductors 211A and 211B are prevented from coming into contact with each other and the intermediate conductors 211A and 211B are biased toward the front surface side and the back surface side of the heat dissipation sheet 210.

Because the insulation sheets 213A to 213C are formed of a resin-based member, same have no small number of voids. However, in the heat dissipation sheet 210 illustrated in FIG. 8, because the insulation sheet has a three-layer structure, it is possible to prevent voids penetrating the heat dissipation sheet 210, that is, a state in which defects such as voids in the insulation sheets 213A to 213C of the respective layers are aligned so as to overlap each other in the y direction. Therefore, it is possible to prevent a reduction in insulation performance due to the influence of the overlapping of defects.

Also in the case of the configuration of FIG. 8, the interval d5 in the x direction between the intermediate conductors 211A and 211B is set such that d5≥0. However, in a case where the influence on the voltage division is negligible, such as a case where the potential difference between the intermediate conductors 211A and 211B is small, d5<0 may be satisfied.

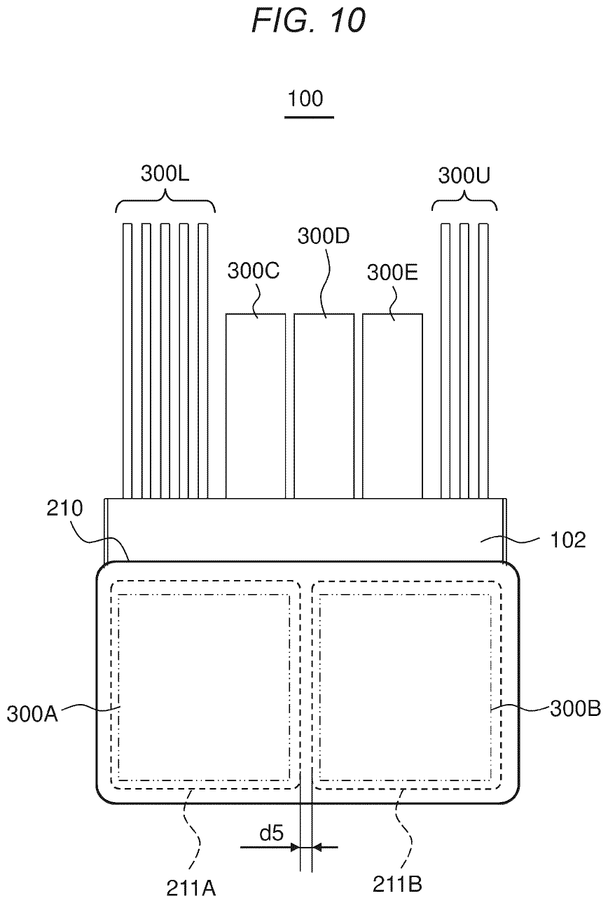

FIG. 10 is a diagram illustrating the heat dissipation sheet 210 provided on the side of the upper arm base 300B and the lower arm base 300A of the circuit molded body 101. In the example illustrated in FIG. 10, the intermediate conductors 211A and 211B are larger than the areas of the upper arm base 300B and the lower arm base 300A facing each other, and extend to the regions around the upper arm base 300B and the lower arm base 300A. Although not illustrated, the AC lead frame 302 side and the N lead frame 301 side have the same structure.

As described above, because the region size of the intermediate conductors 211 (211A, 211B) is larger than the region size of the conductor member (upper arm base 300B, lower arm base 300A, AC lead frame 302, N lead frame 301), an allowable range for the size and position of the intermediate conductors 211 is widened, and productivity can be improved. Further, the margin for the positional displacement of the heat dissipation sheet 210 relative to the circuit molded body 101 can be increased.

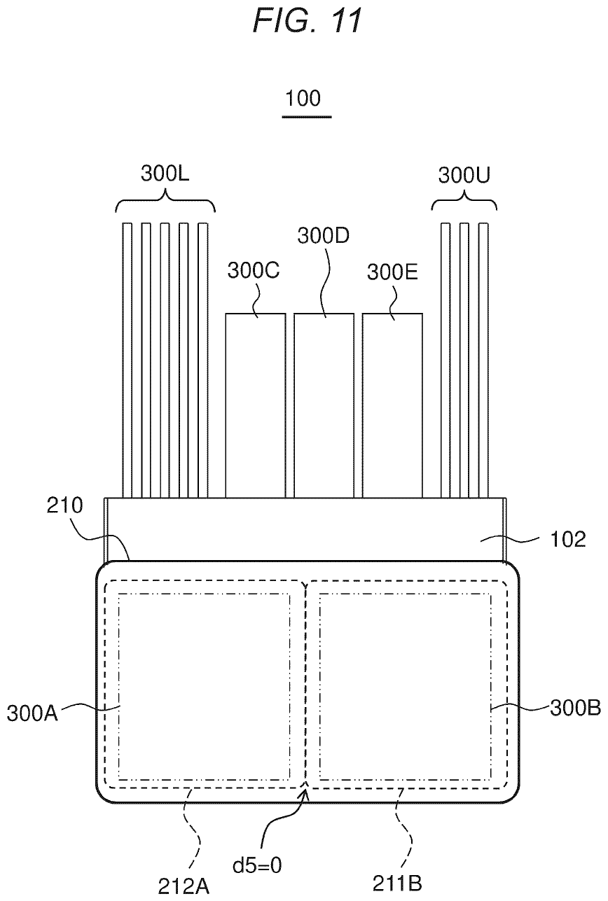

FIG. 11 is a diagram similar to FIG. 10, but illustrates a case where the intermediate conductor 211 is larger than that in the case of FIG. 10 and where d5=0 is set. Because the intermediate conductors 211A and 211B are arranged between different insulation sheet layers as illustrated in FIG. 8, the intermediate conductors 211A and 211B do not come into contact with each other even when d5=0.

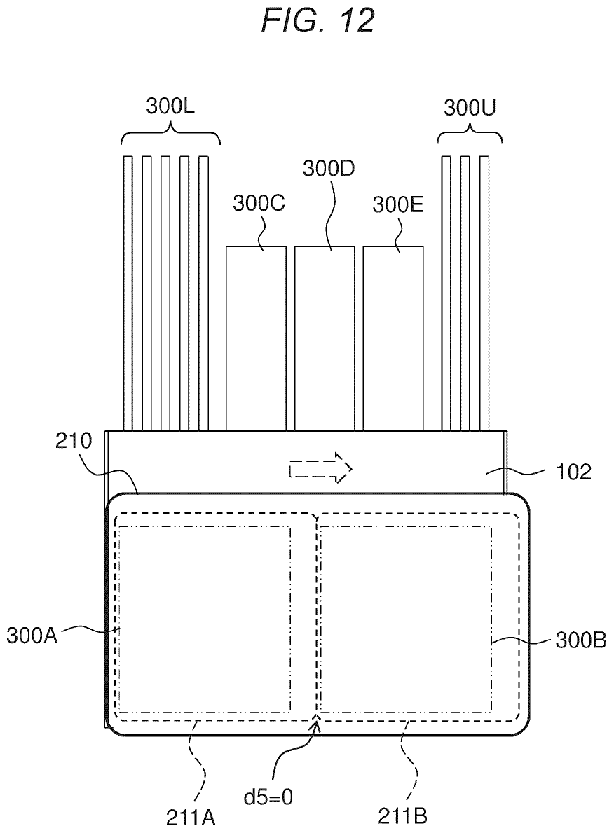

In the case of FIG. 11, in comparison with FIG. 10, the allowable range for positional displacement of the heat dissipation sheet 210 is further expanded within a range in which the two intermediate conductors 211A and 211B cover the upper arm base 300B and the lower arm base 300A. FIG. 12 is a diagram illustrating a state in which the heat dissipation sheet 210 is shifted rightward in the drawing. Even if the heat dissipation sheet 210 is positionally displaced in this manner, each intermediate conductor 211 can cover the entirety of the opposing surfaces of the upper arm base 300B and the lower arm base 300A, and the allowable range for positional displacement of the heat dissipation sheet 210 is large. As a result, assembly workability can be improved.

In the above-described embodiment, the single-phase power module 100 of the inverter circuit has been described as an example. In the power module 100, a circuit molded body 101 for one phase is housed in the case 200. However, the configuration of the present embodiment can be similarly applied to a semiconductor device having a configuration in which a plurality of circuit molded bodies 101 are housed in one case.

According to the embodiment of the present invention described above, the following operational effects are yielded.

(C1) As illustrated in FIG. 5, the power module 100, which is a semiconductor device, includes an upper arm base 300B constituting a first conductor member to which the power semiconductor element 303U on an upper arm side of the inverter circuit is connected; a lower arm base 300A constituting a second conductor member to which the power semiconductor element 303L on a lower arm side of the inverter circuit is connected; a heat dissipation member 201 arranged to face the upper arm base 300B and the lower arm base 300A arranged in parallel; and a heat dissipation sheet 210 constituting an insulating member that includes an intermediate conductor 211B facing the upper arm base 300B, an intermediate conductor 211A facing the lower arm base 300A, and an electrical insulation layer 212 that contains the intermediate conductors 211A and 211B, the heat dissipation sheet 210 being arranged between the upper arm base 300B and the lower arm base 300A arranged in parallel, and the heat dissipation member 201. The electrical insulation layer 212 includes a first insulation layer L1 where the first intermediate conductor 211B is disposed, a second insulation layer L2 where the intermediate conductor 211A is disposed, and a third insulation layer L3 interposed between the first insulation layer L1 and the second insulation layer L2.

Because the third insulation layer L3 is interposed, so as to be stacked, between the intermediate conductor 211A and the intermediate conductor 211B, it is possible to prevent contact between the intermediate conductors 211A and 211B due to positional displacement or the like of the intermediate conductors 211A and 211B. In addition, in the manufacture of the heat dissipation sheet 210, an allowable range regarding the size and positioning accuracy of the intermediate conductors 211A and 211B is widened, and productivity can also be improved.

(C2) Furthermore, the intermediate conductors 211A and 211B are set to either the first arrangement state in which the distance d4 from the lower arm base 300A to the heat dissipation member side-facing surface of the intermediate conductor 211A is set to be smaller than the distance d1 from the upper arm base 300B to the conductor member side-facing surface of the intermediate conductor 211B as illustrated in FIG. 5, or the second arrangement state in which the distance d2 from the N lead frame 301 to the conductor member side-facing surface of the intermediate conductor 211A is set to be larger than the distance d3 from the AC lead frame 302 to the heat dissipation member side-facing surface of the intermediate conductor 211B, as illustrated in FIG. 6. In both the first arrangement state and the second arrangement state, contact between the intermediate conductors 211A and 211B can be prevented.

(C3) In (C2) above, the first arrangement state illustrated in FIG. 5 is set in a case where a direct current flows through the upper arm base 300B and an alternating current flows through the lower arm base 300A, and the second arrangement state illustrated in FIG. 6 is set in a case where an alternating current flows through the AC lead frame 302 and a direct current flows through the N lead frame 301. By bringing the intermediate conductor facing the conductor member (lower arm base 300A, AC lead frame 302) through which the alternating current flows closer to the conductor member than the side through which the direct current flows, it is possible to suppress the occurrence of corona discharge on the alternating current side and to improve insulation.

(C4) In (C1) above, as illustrated in FIG. 8, the heat dissipation sheet 210 includes an insulation sheet 213B having a region facing the intermediate conductors 211A and 211B and formed of an electrically insulating material, wherein the intermediate conductor 211B is stacked on one surface of the insulation sheet 213B, and the intermediate conductor 211A is stacked on the other surface of the insulation sheet 213B. The insulation n sheet 213B is interposed between the intermediate conductor 211A and the intermediate conductor 211B in the stacking direction, and therefore contact between the intermediate conductors 211A and 211B is prevented, the accuracy of the sizes and positions of the intermediate conductors 211A and 211B can be made approximate, and the intermediate conductors 211A and 211B can be made large. Thus, assembly workability can be improved.

(C5) In (C4) above, as illustrated in FIG. 8, the heat dissipation sheet 210 further includes insulation sheets 213A and 213C having the same shape as the insulation sheet 213B and formed of an electrically insulating material, wherein the insulation sheet 213A is stacked on one surface (lower surface in the drawing) of the insulation sheet 213B on which the intermediate conductor 211B is stacked, and the insulation sheet 213C is stacked on the other surface (upper surface in the drawing) of the insulation sheet 213B on which the intermediate conductor 211A is stacked. By using the insulation sheets 213A, 213B, and 213C having the same shape as described above, components are shared, and hence the types of components are reduced and productivity is improved.

In addition, in a case where a resin-based material is used as the electrically insulating material, voids are easily generated. Therefore, by adopting a structure in which the electrical insulation layer 212 of the heat dissipation sheet 210 is formed by stacking the three insulation sheets 213A, 213B, and 213C, the possibility of voids of the respective insulation sheets overlapping in the same position can be reduced, and thus the insulation reliability can be improved.

(C6) In (C5) above, as illustrated in FIG. 9, the intermediate conductor 211B is fixed to the insulation sheet 213A, the intermediate conductor 211A is fixed to the insulation sheet 213C, and the heat dissipation sheet 210 is formed by stacking the insulation sheet 213A to which the intermediate conductor 211B is fixed, the insulation sheet 213B, and the insulation sheet 213C to which the intermediate conductor 211A is fixed.

In a case where the heat dissipation sheet 210 including the intermediate conductors 211A and 211B is to be manufactured, two intermediate conductor-attached sheets 214, which are obtained by fixing the intermediate conductor 211 to one surface of the heat dissipation sheet 213, and one heat dissipation sheet 213 are prepared. Further, as illustrated in FIG. 9, the intermediate conductor-attached sheet 214 is stacked on both the front and back surfaces of the heat dissipation sheet 213 such that the intermediate conductor 211 faces toward the heat dissipation sheet 213 side. As described above, by using the intermediate conductor-attached sheet 214 to which the intermediate conductor 211 is fixed, the number of component types can be reduced to two, and thus the productivity of the heat dissipation sheet 210 can be improved.

(C7) In (C5) above, as illustrated in FIG. 10, the intermediate conductors 211A and 211B are formed of conductor materials having the same shape. As described above, by using the intermediate conductors 211A and 211B having the same shape, types of components can be reduced, and productivity of the heat dissipation sheet 210 can be improved.

(C8) As illustrated in FIG. 5, the plate-like heat dissipation sheet 210 used for the power module 100 in (C1) above includes: an intermediate conductor 211B disposed in a region of the heat dissipation sheet 210 opposed by the upper arm base 300B; an intermediate conductor 211A disposed in a region of the heat dissipation sheet 210 opposed by the lower arm base 300A; and an electrical insulation layer 212 that includes a first insulation layer L1 in which the intermediate conductor 211B is disposed, a second insulation layer L2 in which the intermediate conductor 211A is disposed, and a third insulation layer L3 interposed between the first insulation layer L1 and the second insulation layer L2, the electrical insulation layer containing the intermediate conductors 211A and 211B. With such a configuration, it is possible to suppress contact between the intermediate conductors 211A and 211B due to positional displacement of the intermediate conductors 211A and 211B in the heat dissipation sheet 210.

The embodiments and various modifications described above are merely examples, and the present invention is not limited to or by the details of these embodiments and modifications as long as the characteristics of the invention are not impaired. Various embodiments and modifications have been described above, but the present invention is not limited to or by the details of these embodiments and modifications. Other aspects which are conceivable within the scope of the technical concepts of the present invention are also included within the scope of the present invention.

### REFERENCE SIGNS LIST

100 power module
101 circuit molded body
200 case
201 heat dissipation member
210 heat dissipation sheet
211, 211A, 211B intermediate conductor
212 electrical insulation layer
213, 213A, 213B, 213C insulation sheet
214 intermediate conductor-attached sheet
300A lower arm base
300B upper arm base
301 N lead frame
302 AC lead frame
303L, 3030 power semiconductor element
304L, 304U diode
L1 first insulation layer
L2 second insulation layer
L3 third insulation layer

1. A semiconductor device, comprising:
a first conductor member to which a switching element on an upper arm side of an inverter circuit is connected;
a second conductor member to which a switching element on a lower arm side of the inverter circuit is connected;
a heat dissipation member arranged to face the first and second conductor members arranged in parallel; and
an insulating member having an electrical insulation layer that contains a first intermediate conductor facing the first conductor member, a second intermediate conductor facing the second conductor member, and the first and second intermediate conductors, the insulating member being disposed between the first and second conductor members arranged in parallel and the heat dissipation member,
wherein the electrical insulation layer has a first insulation layer where the first intermediate conductor is disposed, a second insulation layer where the second intermediate conductor is disposed, and a third insulation layer interposed between the first insulation layer and the second insulation layer.

2. The semiconductor device according to claim 1,
wherein the first and second intermediate conductors are
set to either a first arrangement state in which a distance from the second conductor member to a heat dissipation member side-facing surface of the second intermediate conductor is set to be smaller than a distance from the first conductor member to a conductor member side-facing surface of the first intermediate conductor, or a second arrangement state in which a distance from the second conductor member to a conductor member side-facing surface of the second intermediate conductor is set to be larger than a distance from the first conductor member to a heat dissipation member side-facing surface of the first intermediate conductor.

3. The semiconductor device according to claim 2,
wherein the first arrangement state is set in a case where a direct current flows through the first conductor member and an alternating current flows through the second conductor member, and
the second arrangement state is set in a case where an alternating current flows through the first conductor member and a direct current flows through the second conductor member.

4. The semiconductor device according to claim 1,
wherein the insulating member includes a first insulation sheet having a region facing the first and second intermediate conductors and formed of an electrically insulating material, and
the first intermediate conductor is stacked on one surface of the first insulation sheet, and the second intermediate conductor is stacked on the other surface of the first insulation sheet.

5. The semiconductor device according to claim 4,
wherein the insulating member further includes second and third insulation sheets having the same shape as the first insulation sheet and formed of the electrically insulating material,
the second insulation sheet is stacked on one surface of the first insulation sheet 213B on which the first intermediate conductor is stacked, and
the third insulation sheet is stacked on the other surface of the first insulation sheet 213B on which the second intermediate conductor is stacked.

6. The semiconductor device according to claim 5,
wherein the first intermediate conductor is fixed to the second insulation sheet,
the second intermediate conductor is fixed to the third insulation sheet, and
the insulating member is formed by stacking the second insulation sheet to which the first intermediate conductor is fixed, the first insulation sheet, and the third insulation sheet to which the second intermediate conductor is fixed.

7. The semiconductor device according to claim 5,
wherein the first and second intermediate conductors are formed of conductor materials having the same shape.

8. A plate-shaped insulating member used in the semiconductor device according to claim 1, the insulating member comprising:
the first intermediate conductor disposed in a first region of the insulating member;
the second intermediate conductor disposed in a second region different from the first region of the insulating member; and
the electrical insulation layer that includes: the first insulation layer where the first intermediate conductor is disposed, the second insulation layer where the second intermediate conductor is disposed, and the third insulation layer interposed between the first insulation layer and the second insulation layer, the electrical insulation layer containing the first and second intermediate conductors.
